(19) United States
(12) Patent Application Publication
(10) Pub. No.: US 2025/0346784 A1
(43) Pub. Date: Nov. 13, 2025

(54) COMPOSITION FOR CHEMICAL MECHANICAL POLISHING AND POLISHING METHOD

(71) Applicant: JSR CORPORATION, Tokyo (JP)

(72) Inventors: Yuya YAMADA, Tokyo (JP); Shen-Yuan KAO, Tokyo (JP)

(73) Assignee: JSR CORPORATION, Tokyo (JP)

(21) Appl. No.: 18/870,440

(22) PCT Filed: Aug. 15, 2023
(86) PCT No.: PCT/JP2023/029521

§ 371 Date: Nov. 28, 2024

(30) Foreign Application Priority Data
Sep. 1, 2022 (JP) 2022-139064

(51) Int. Cl. C09G 1/02; H01L 21/321

(52) U.S. Cl. CPC C09G 1/02; H01L 21/3212

(57) ABSTRACT

Provided are: a composition for chemical mechanical polishing; and a polishing method using the same. The composition allows rapid polishing of a polishing surface that contains a silver material for wiring, and makes it possible to obtain a polished surface having a high reflective property. This composition for chemical mechanical polishing comprises (A) abrasive grains, (B) a liquid medium, (C) an oxidizing agent, and (D) a nitrogen-containing hetrocyclic compound. The absolute value of the zeta potential of the (A) component of the composition for chemical mechanical polishing is 10 mV or more. When the content of the (C) component is noted as Mc (mass %) and the content of the (D) component is noted as Md (mass %), Mc/Md is 10 to 200.

### TECHNICAL FIELD

The invention relates to a composition for chemical mechanical polishing and a polishing method using the same.

### RELATED ART

Chemical mechanical polishing (hereinafter also referred to as “CMP”) is utilized in a semiconductor manufacturing process, particularly in planarizing an interlayer insulating film for a multilayer wiring formation process, forming a metal plug, and forming an embedded wiring (damascene wiring). In such semiconductor manufacturing process, CMP is required not only to perform high-speed polishing of an insulating material such as silicon oxide, a barrier material such as tantalum nitride, and a wiring material such as aluminum and copper, but also to achieve balanced polishing properties with high planarity and low defects for these materials.

In recent years, studies have been conducted to replace copper with silver as the wiring material to obtain a higher-performance semiconductor device. Silver has the properties of lower resistivity and higher electromigration stability than the properties of copper. Therefore, silver has the potential to contribute to the enhancement of semiconductor device performance and is expected to serve as an effective wiring material (see, for example, Patent Documents 1, 2).

### CITATION LIST

### Patent Literature

Patent Document 1: Japanese Laid-open No. 2005-518669
Patent Document 2: Japanese Laid-open No. 2014-507799

### SUMMARY OF INVENTION

### Technical Problem

However, since silver has significantly different properties from copper, conventional copper wiring polishing slurries cannot be directly applied. It is necessary to suppress silver residue on wiring patterns or corrosion or polishing scratches of wiring portions due to chemical components in the polishing liquid by using a technique different from conventional techniques used for copper and aluminum.

Several aspects of the invention are provided for a composition for chemical mechanical polishing; and a polishing method using the same. The composition allows rapid polishing of a polishing surface that contains a silver material for wiring, and makes it possible to obtain a polished surface having a high reflective property.

### Solution to Problem

An aspect of a composition for chemical mechanical polishing according to the invention includes: (A) abrasive grains; (B) a liquid medium; (C) an oxidizing agent; and (D) a nitrogen-containing heterocyclic compound. An absolute value of a zeta potential of (A) in the composition for chemical mechanical polishing is 10 mV or more. In a case where a content of (C) is set as Me (in mass %), and a content of (D) is set as Md (in mass %), Mc/Md=100 to 200.

In an aspect of the composition for chemical mechanical polishing, it may also be that (A) may have a functional group represented by General Formula (1) as follows:

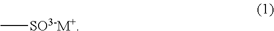

(M⁺ represents a monovalent cation.)

In an aspect of the composition for chemical mechanical polishing, it may also be that the zeta potential of (A) in the composition for chemical mechanical polishing is −10 mV or less.

In an aspect of the composition for chemical mechanical polishing, it may also be that (A) may have a functional group represented by General Formula (2) as follows:

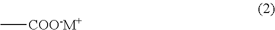

(M⁺ represents a monovalent cation.)

In an aspect of the composition for chemical mechanical polishing, it may also be that the zeta potential of (A) in the composition for chemical mechanical polishing is −10 mV or less.

In an aspect of the composition for chemical mechanical polishing, it may also be that (A) has a functional group represented by General Formula (3) or General Formula (4) as follows:

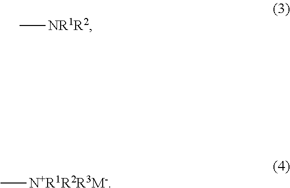

(In General Formula (3) and General Formula (4), R¹, R², and R³ each independently represent a hydrogen atom, or a substituted or unsubstituted hydrocarbon group, and M− represents an anion.)

In an aspect of the composition for chemical mechanical polishing, it may also be that the zeta potential of (A) in the composition for chemical mechanical polishing is 10 mV or more.

In an aspect of the composition for chemical mechanical polishing, it may also be that the composition has a pH of 1 or more and 6 or less.

In an aspect of the composition for chemical mechanical polishing, it may also be that, with respect to a total mass of the composition for chemical mechanical polishing, a content of (A) is 0.005 mass % or more and 15 mass % or less.

In an aspect of the composition for chemical mechanical polishing, it may also be that (D) has an azole structure.

An aspect of a polishing method according to the invention includes: a step of polishing a semiconductor substrate by using the composition for chemical mechanical polishing as claimed in any one of the above.

In an aspect of the polishing method, it may also be that the semiconductor substrate includes a portion containing silver.

### Effects of Invention

According to the composition for chemical mechanical polishing related to the invention, it is possible to polish a polished surface containing silver as a wiring material at high speed, and effectively reduce the occurrence of corrosion or polishing scratches on the polished surface after polishing, thereby obtaining a polished surface with excellent high reflective properties.

### BRIEF DESCRIPTION OF DRAWINGS

FIG. 1 is a cross-sectional view schematically showing a processed body suitable for use in a polishing method according to the embodiment.

FIG. 2 is a cross-sectional view schematically showing a processed body at the end of a first polishing step.

FIG. 3 is a cross-sectional view schematically showing a processed body at the end of a second polishing step.

FIG. 4 is a perspective view schematically showing a chemical mechanical polishing device.

### DESCRIPTION OF EMBODIMENTS

The following describes in detail exemplary embodiments of the invention. It should be noted that the invention is not limited to the embodiments described below, and includes various modified examples implemented within a range that does not depart from the gist of the invention.

In the specification, “wiring material” refers to a conductive metal material such as aluminum, copper, silver, gold, cobalt, titanium, ruthenium, tungsten, etc. “Insulating film material” refers to materials such as silicon dioxide, silicon nitride, amorphous silicon, hafnium oxide, etc. “Barrier metal material” refers to materials such as tantalum nitride, titanium nitride, etc., which are used to laminate the wiring material to improve wiring reliability.

In the specification, a numerical range described using “X to Y” is interpreted to include the numerical value X as the lower limit and the numerical value Y as the upper limit.

### 1. COMPOSITION FOR CHEMICAL MECHANICAL POLISHING

The composition for chemical mechanical polishing according to an embodiment of the invention includes: (A) abrasive grains (also referred to as “Component (A)” in the specification); (B) a liquid medium (also referred to as “Component (B)” in the specification); (C) an oxidizing agent (also referred to as “Component (C)” in the specification); and (D) nitrogen-containing heterocyclic compound (also referred to as “Component (D)” in the specification). The absolute value of the zeta potential of Component (A) in the composition for chemical mechanical polishing is 10 mV or more. The following describes in detail each component included in the composition for chemical mechanical polishing according to the embodiment.

### 1.1 (A) Component

The composition for chemical mechanical polishing according to the embodiment includes (A) abrasive grains. Component (A) is not particularly limited as long as the absolute value of zeta potential thereof is 10 mV or more in the composition for chemical mechanical polishing.

The abrasive grains can be manufactured by applying methods described in Japanese Laid-Open No. 2007-153732 or Japanese Laid-Open No. 2013-121631, for example. By modifying at least a portion of the surfaces of the abrasive grains obtained in this way with a functional group, abrasive grains with the absolute value of the zeta potential of 10 mV or more in the composition for chemical mechanical polishing can be manufactured.

The absolute value of the zeta potential of Component (A) in the composition for chemical mechanical polishing is 10 mV or more, preferably 15 mV or more, and more preferably 20 mV or more. The absolute value of the zeta potential of Component (A) in the composition for chemical mechanical polishing is preferably 40 mV or less. When the absolute value of the zeta potential of Component (A) in the composition for chemical mechanical polishing is within the range, the dispersibility of the abrasive grains in the composition for chemical mechanical polishing improves due to the electrostatic repulsion force between the abrasive grains. As a result, high-speed polishing of the polished surface can be performed while reducing the occurrence of polishing scratches and dishing on the polished surface.

The average secondary particle diameter of Component (A) is preferably 5 nm or more and 200 nm or less, and more preferably 10 nm or more and 100 nm or less. When the average secondary particle diameter of Component (A) is within the range, a sufficient polishing rate can be obtained, and a composition for chemical mechanical polishing with excellent stability that does not cause particle sedimentation or separation may be obtained. The average secondary particle diameter of Component (A) can be calculated and determined by using a dynamic light scattering method, for example, using “Zetasizer Ultra” manufactured by Malvern Instruments.

The shape of Component (A) is not particularly limited and may be spherical or non-spherical. In the case where the shape of Component (A) is non-spherical, it is preferable to have a shape with multiple protrusions on the surface. The protrusions referred to here have a height and a width sufficiently smaller than the particle diameter of the abrasive grains. The number of the protrusions provided on the surface of Component (A) is preferably, on average, 3 or more per abrasive grain, and more preferably 5 or more. That Component (A) has a shape with multiple protrusions on the surface can also be described as abrasive grains having a unique shape like a so-called confetti-like shape. By having such a unique shape, Component (A) can exhibit a higher polishing rate of the polished surface containing silver than the rate of the case using spherical abrasive grains. In addition, due to the unique shape of Component (A), the surface area increases. Thus, the reactivity with a compound having a functional group as described later is increased. As a result, the absolute value of the zeta potential of Component (A) in the composition for chemical mechanical polishing increases, and the dispersibility improves. Consequently, high-speed polishing of the polished surface can be performed while reducing the occurrence of polishing scratches and dishing on the polished surface.

Component (A) preferably includes silica as a main component. In the case where Component (A) includes silica as a main component, it may further include other components. Examples of other components include aluminum compounds, silicon compounds, etc. By further including aluminum compounds or silicon compounds in Component (A), the surface hardness of Component (A) can be reduced, so the occurrence of polishing scratches and dishing on the polished surface can be reduced.

Examples of aluminum compounds include aluminum hydroxide, aluminum oxide (alumina), aluminum chloride, aluminum nitride, aluminum acetate, aluminum phosphate, aluminum sulfate, sodium aluminate, potassium aluminate, etc. On the other hand, examples of silicon compounds include silicon nitride, silicon carbide, silicates, silicone, silicon resin, etc.

Component (A) is preferably abrasive grains with at least a portion of the surfaces thereof modified by a functional group. The abrasive grains with at least a portion of the surface modified by a functional group have a larger absolute value of zeta potential in the pH range of 1 or more and 6 or less than abrasive grains without surface modification by the functional group. As a result, the electrostatic repulsion force between the abrasive grains increases. As a result, the dispersibility of the abrasive grains in the composition for chemical mechanical polishing improves, enabling high-speed polishing while reducing the occurrence of polishing scratches and dishing on the polished surface.

The following describes in detail the specific embodiments of Component (A).

### 1.1.1 First Embodiment

As the first embodiment of Component (A), abrasive grains having a functional group represented by the following general formula (1) can be listed.

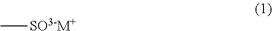

(M⁺ represents a monovalent cation.)

The monovalent cation represented by M+ in the above formula (1) includes, but is not limited to, H⁺, Li⁺, Na⁺, K⁺, NH4⁺. In other words, the functional group represented by the above general formula (1) can also be rephrased as “at least one functional group selected from the group consisting of a sulfo group and a salt thereof”. Here, “salt of a sulfo group” refers to a functional group in which the hydrogen ion included in the sulfo group (—SO₃H) is substituted with a monovalent cation such as Li⁺, Na⁺, K⁺, NH4⁺, etc. Component (A) according to the first embodiment is abrasive grains with the functional group represented by the above general formula (1) fixed to the surface thereof via a covalent bond, and does not include abrasive grains to which a compound having the functional group represented by the above general formula (1) are physically or ionically adsorbed on the surface.

Component (A) according to the first embodiment can be manufactured as follows. Firstly, silica particles are prepared by applying the method described in Japanese Laid-Open No. 2007-153732 or Japanese Laid-Open No. 2013-121631. Next, the silica particles and a mercapto group-containing silane coupling agent are sufficiently stirred in an acidic medium to covalently bond the mercapto group-containing silane coupling agent to the surface of the silica particles. Examples of the mercapto group-containing silane coupling agent include 3-mercaptopropylmethyldimethoxysilane, 3-mercaptopropyltrimethoxysilane, etc. Then, by adding an appropriate amount of hydrogen peroxide and allowing it to stand for a sufficient time, abrasive grains having the functional group represented by the above general formula (1) can be obtained.

The zeta potential of Component (A) according to the first embodiment is negative in the composition for chemical mechanical polishing, and this negative potential is preferably −10 mV or less, more preferably −15 mV or less, and particularly preferably −20 mV or less. When the zeta potential of Component (A) according to the first embodiment is within the range, it can effectively prevent particle aggregation through the electrostatic repulsion force between the abrasive grains, and the abrasive grains may be able to selectively polish a substrate that is positively charged at the time of chemical mechanical polishing. Examples of the zeta potential measuring device include “ELSZ-2000ZS” manufactured by Otsuka Electronics Co., Ltd. and “Zetasizer nano zs” manufactured by Malvern. The zeta potential of Component (A) according to the first embodiment can be adjusted by appropriately increasing or decreasing the addition amount of, for example, the mercapto group-containing silane coupling agent.

In the case where the composition for chemical mechanical polishing according to the embodiment includes Component (A) according to the first embodiment, the content of Component (A) according to the first embodiment is preferably 0.005 mass % or more, more preferably 0.1 mass % or more, and particularly preferably 0.5 mass % or more, when the total mass of the composition for chemical mechanical polishing is taken as 100 mass %. The content of Component (A) according to the first embodiment is preferably 15 mass % or less, more preferably 8 mass % or less, and particularly preferably 5 mass % or less, when the total mass of the composition for chemical mechanical polishing is taken as 100 mass %. When the content of Component (A) according to the first embodiment is within the range, it may be possible to perform high-speed polishing of a polished surface containing silver, while making the storage stability of the composition for chemical mechanical polishing favorable.

### 1.1.2 Second Embodiment

As the second embodiment of Component (A), abrasive grains having a functional group represented by the following general formula (2) can be listed.

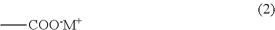

(M⁺ represents a monovalent cation.)

The monovalent cation represented by M+ in the above formula (2) includes, but is not limited to, H⁺, Li⁺, Na⁺, K⁺, NH4⁺. In other words, the functional group represented by the above general formula (2) can also be rephrased as “at least one functional group selected from the group consisting of a carboxyl group and a salt thereof”. Here, “salt of carboxyl group” refers to a functional group in which the hydrogen ion included in the carboxyl group (—COOH) is substituted with a monovalent cation such as Li⁺, Na⁺, K⁺, NH4⁺, etc. Component (A) according to the second embodiment is abrasive grains with the functional group represented by the above general formula (2) fixed to the surfaces thereof via a covalent bond, and does not include abrasive grains to which a compound having the functional group represented by the above general formula (2) are physically or ionically adsorbed on the surface.

Component (A) according to the second embodiment can be manufactured as follows. Firstly, silica particles are prepared by applying the method described in Japanese Laid-Open No. 2007-153732 or Japanese Laid-Open No. 2013-121631. Then, by sufficiently stirring silica particles and a carboxylic acid anhydride-containing silane coupling agent in a basic medium to covalently bond the carboxylic acid anhydride-containing silane coupling agent to the surface of the silica particles, abrasive grains having the functional group represented by the above general formula (2) can be obtained. As the carboxylic acid anhydride-containing silane coupling agent, for example, 3-(triethoxysilyl)propylsuccinic anhydride and the like can be listed.

The zeta potential of Component (A) according to the second embodiment is negative in the composition for chemical mechanical polishing, and this negative potential is preferably −10 mV or less, more preferably −15 mV or less, and particularly preferably −20 mV or less. When the zeta potential of Component (A) according to the second embodiment is within the range, it can effectively prevent particle aggregation through the electrostatic repulsion force between the abrasive grains, and the abrasive grains may be able to selectively polish a substrate that is positively charged at the time of chemical mechanical polishing. For the zeta potential measuring device, the device described in the first embodiment can be used. The zeta potential of Component (A) according to the second embodiment can be adjusted by appropriately increasing or decreasing the amount of an additive, such as the carboxylic acid anhydride-containing silane coupling agent.

In the case where the composition for chemical mechanical polishing according to the embodiment includes Component (A) according to the second embodiment, the content of Component (A) according to the second embodiment is preferably 0.005 mass % or more, more preferably 0.1 mass % or more, and particularly preferably 0.5 mass % or more, when the total mass of the composition for chemical mechanical polishing is taken as 100 mass %. The content of Component (A) according to the second embodiment is preferably 15 mass % or less, more preferably 8 mass % or less, and particularly preferably 5 mass % or less, when the total mass of the composition for chemical mechanical polishing is taken as 100 mass %. When the content of Component (A) according to the second embodiment is within the range, it may be possible to perform high-speed polishing of a polished surface containing silver, while making the storage stability of the composition for chemical mechanical polishing favorable.

### 1.1.3 Third Embodiment

As the third embodiment of Component (A), abrasive grains having a functional group represented by the following general formula (3) or the following general formula (4) can be listed.

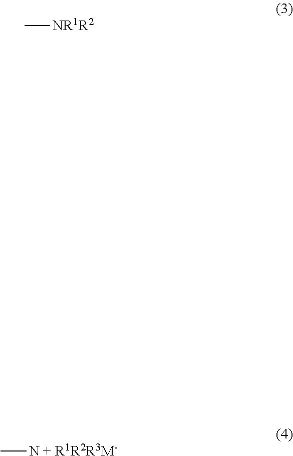

(In the above formula (3) and formula (4), R¹, R², and R³ each independently represent a hydrogen atom, or a substituted or unsubstituted hydrocarbon group, and M− represents an anion.)

The functional group represented by the above general formula (3) represents an amino group, and the functional group represented by the above general formula (4) represents a salt of an amino group. Therefore, the functional group represented by the above general formula (3) and the functional group represented by the above general formula (4) can also be rephrased as “at least one functional group selected from the group consisting of amino groups and salts thereof”. Component (A) according to the third embodiment is abrasive grains with the functional group represented by the above general formula (3) or the above general formula (4) fixed to the surfaces thereof via a covalent bond, and does not include abrasive grains where compounds having the functional group represented by the above general formula (3) or the above general formula (4) are physically or ionically adsorbed on the surfaces thereof.

As the anion represented by M− in the above formula (4), although not limited to these, examples include anions such as OH⁻, F⁻, Cl⁻, Br⁻, I⁻, CN⁻, etc., as well as anions derived from acidic compounds.

In the above formula (3) and formula (4), R¹ to R³ each independently represent a hydrogen atom, or a substituted or unsubstituted hydrocarbon group, but two or more of R¹ to R³ may be bonded to form a ring structure.

The hydrocarbon group represented by R¹ to R³ may be any of an aliphatic hydrocarbon group, an aromatic hydrocarbon group, an aromatic aliphatic hydrocarbon group, or an alicyclic hydrocarbon group. In addition, the aliphatic portions of the aliphatic hydrocarbon group and the aromatic aliphatic hydrocarbon group may be saturated or unsaturated, and may be linear or branched. Examples of the hydrocarbon groups include a linear, branched, cyclic alkyl group, an alkenyl group, an aralkyl group, and an aryl groups.

As the alkyl group, a lower alkyl group with 1 to 6 carbon atoms is preferred, and a lower alkyl group with 1 to 4 carbon atoms is more preferred. Examples of such alkyl group include a methyl group, an ethyl group, an n-propyl group, an iso-propyl group, an n-butyl group, an iso-butyl group, a sec-butyl group, a tert-butyl group, an n-pentyl group, an iso-pentyl group, a sec-pentyl group, a tert-pentyl group, a neopentyl group, an n-hexyl group, an iso-hexyl group, a sec-hexyl group, a tert-hexyl group, a cyclopentyl group, a cyclohexyl group, etc.

As the alkenyl group, a lower alkenyl group with 1 to 6 carbon atoms is preferred, and a lower alkenyl group with 1 to 4 carbon atoms is more preferred. Examples of such alkenyl group include a vinyl group, an n-propenyl group, an iso-propenyl group, an n-butenyl group, an iso-butenyl group, a sec-butenyl group, an tert-butenyl group, etc.

As the aralkyl group, one with 7 to 12 carbon atoms is preferred. Examples of such aralkyl group include a benzyl group, a phenethyl group, a phenylpropyl group, phenylbutyl group, a phenylhexyl group, a methylbenzyl group, a methylphenethyl group, an ethylbenzyl group, etc.

As the aryl group, one with 6 to 14 carbon atoms is preferred. Examples of such aryl group include a phenyl group, an o-tolyl group, an m-tolyl group, a p-tolyl group, a 2,3-xylyl group, a 2,4-xylyl group, a 2,5-xylyl group, a 2,6-xylyl group, a 3,5-xylyl group, an naphthyl group, an anthryl group, etc.

The aromatic rings of the aryl and aralkyl groups may possess a substituent such as a lower alkyl group like a methyl group and an ethyl group, or a halogen atom, an nitro group, an amino group, a hydroxy group, etc.

Component (A) according to the third embodiment can be manufactured as follows. Firstly, silica particles are prepared by applying the method described in Japanese Laid-Open No. 2007-153732 or Japanese Laid-Open No. 2013-121631. Then, silica particles and an amino group-containing silane coupling agent are sufficiently stirred in an acidic medium, and the amino group-containing silane coupling agent is covalently bonded to the surfaces of the silica particles, thereby obtaining the abrasive grains having a functional group represented by the above general formula (3) or (4). Examples of the amino group-containing silane coupling agent include 3-aminopropyltrimethoxysilane, 3-aminopropyltriethoxysilane, etc.

The zeta potential of Component (A) according to the third embodiment is positive in the composition for chemical mechanical polishing, and this positive potential is preferably +10 mV or more, more preferably +15 mV or more, and particularly preferably +20 mV or more. When the zeta potential of Component (A) according to the third embodiment is within the range, it can effectively prevent particle aggregation through an electrostatic repulsion force between the abrasive grains, and the abrasive grains may be able to selectively polish a substrate that is negatively charged at the time of chemical mechanical polishing. For the zeta potential measuring device, the device described in the first embodiment can be used. The zeta potential of Component (A) according to the third embodiment can be adjusted by appropriately increasing or decreasing the amount of an additive, such as the amino group-containing silane coupling agent.

In the case where the composition for chemical mechanical polishing according to the embodiment includes Component (A) according to the third embodiment, the content of Component (A) according to the third embodiment is preferably 0.005 mass % or more, more preferably 0.1 mass % or more, and particularly preferably 0.5 mass % or more, when the total mass of the composition for chemical mechanical polishing is taken as 100 mass %. The content of Component (A) according to the third embodiment is preferably 15 mass % or less, more preferably 8 mass % or less, and particularly preferably 5 mass % or less, when the total mass of the composition for chemical mechanical polishing is taken as 100 mass %. When the content of Component (A) according to the third embodiment is within the range, it may be possible to perform high-speed polishing of a polished surface containing silver, while making the storage stability of the composition for chemical mechanical polishing favorable.

### 1.2 (B) Liquid Medium

The composition for chemical mechanical polishing according to the embodiment includes (B) a liquid medium. Examples of Component (B) include water, a mixed medium of water and alcohol, and a mixed medium containing water and an organic solvent having compatibility with water. Among these, it is preferable to use water or a mixed medium of water and alcohol, and it is more preferable to use water. Although there is no particular limitation on the water, pure water is preferable. The water may be included as the remainder of the constituent materials of the composition for chemical mechanical polishing, and there is no particular limitation on the content of water.

### 1.3 (C) Oxidizing Agent

The composition for chemical mechanical polishing according to the embodiment includes (A) an oxidizing agent. By including Component (C), it is possible to oxidize the polished surface containing silver to create a fragile modified layer, and perform high-speed polishing on the polished surface. Examples of Component (C) include an organic peroxide such as hydrogen peroxide, peracetic acid, perbenzoic acid, and tert-butyl hydroperoxide; a permanganate compound such as potassium permanganate; a dichromate compound such as potassium dichromate; a halogen oxide such as potassium iodate; a nitrate compound such as ferric nitrate; a perhalogen oxide such as perchloric acid; a persulfate such as ammonium persulfate; and a heteropoly acid. Among these, organic peroxide is preferable, and hydrogen peroxide is more preferable. The oxidizing agents may be used alone or in combination of two or more.

The content of Component (C) in the composition for chemical mechanical polishing according to the embodiment is preferably 0.01 mass % or more, more preferably 0.1 mass % or more, and particularly preferably 0.4 mass % or more, when the total mass of the composition for chemical mechanical polishing is taken as 100 mass %. The content of Component (C) is preferably 5 mass % or less, more preferably 3 mass % or less, and particularly preferably 1 mass % or less, when the total mass of the composition for chemical mechanical polishing is taken as 100 mass %.

### 1.4. (D) Nitrogen-Containing Heterocyclic Compound

The composition for chemical mechanical polishing according to the embodiment includes (D) a nitrogen-containing heterocyclic compound. Component (D) is adsorbed to the polished surface containing silver, thereby protecting the polished surface. Accordingly, the occurrence of corrosion or polishing scratches on the polished surface after polishing can be effectively reduced, thereby obtaining a polished surface with excellent high reflective properties. A nitrogen-containing heterocyclic compound refers to an organic compound containing at least one heterocyclic ring selected from a five-membered heterocyclic ring and a six-membered heterocyclic ring and having at least one nitrogen atom. Examples of the nitrogen heterocycle include a five-membered heterocyclic ring, such as a pyrrole structure, an imidazole structure, and a triazole structure; a six-membered heterocyclic ring such as a pyridine structure, a pyrimidine structure, a pyridazine structure, and a pyrazine structure. The heterocyclic rings may form fused rings. Specifically, examples include an indole structure, an isoindole structure, a benzimidazole structure, a benzotriazole structure, a quinoline structure, an isoquinoline structure, a quinazoline structure, a cinnoline structure, a phthalazine structure, a quinoxaline structure, and an acridine structure. Among the heterocyclic compounds having such structures, a heterocyclic compound having a pyridine structure, a quinoline structure, a benzimidazole structure, and a benzotriazole structure are preferable.

Specific examples of the nitrogen-containing heterocyclic compound include aziridine, pyridine, pyrimidine, pyrrolidine, piperidine, pyrazine, triazine, pyrrole, imidazole, indole, quinoline, isoquinoline, benzoisoquinoline, purine, pteridine, triazole, triazolidine, benzotriazole, carboxybenzotriazole, and derivatives having the skeletons. Among these, a compound having an azole structure is preferable, and it is more preferable to select at least one from triazole, benzotriazole, carboxybenzotriazole, and derivatives having these skeletons. The nitrogen-containing heterocyclic compounds may be used alone or in combination of two or more.

The content of Component (C) in the composition for chemical mechanical polishing according to the embodiment is preferably 0.001 mass % or more, more preferably 0.005 mass % or more, and particularly preferably 0.01 mass % or more, when the total mass of the composition for chemical mechanical polishing is taken as 100 mass %. The content of Component (D) is preferably 1 mass % or less, more preferably 0.1 mass % or less, and particularly preferably 0.07 mass % or less, when the total mass of the composition for chemical mechanical polishing is taken as 100 mass %.

In addition, in the composition for chemical mechanical polishing according to the embodiment, it is necessary to maintain the content ratios of Component (C) and Component (D) within specified ranges. In the composition for chemical mechanical polishing according to the embodiment, when the content of Component (C) is Mc (mass %) and the content of Component (D) is Md (mass %), the value of Mc/Md is 10 or more, preferably 11 or more, and more preferably 12 or more. Also, the value of Mc/Md is 200 or less, preferably 190 or less, and more preferably 185 or less. When the value of Mc/Md is within the range, a good balance is achieved between the effect of high-speed polishing of the polished surface containing silver and the effect of reducing corrosion and polishing scratches on the polished surface after polishing, allowing these effects to be realized simultaneously.

### 1.5 Other Components

The composition for chemical mechanical polishing according to the embodiment may include, in addition to the respective components mentioned above, organic acids and salts thereof, phosphate esters, water-soluble polymers, surfactants, inorganic acids and salts thereof, basic compounds, etc., as necessary.

### <Organic Acids and Salts Thereof>

The composition for chemical mechanical polishing according to the embodiment may also include at least one selected from the group consisting of organic acids and salts thereof (hereinafter also referred to as “organic acid (salt)”). Organic acids and salts thereof may further increase the polishing rate of the polished surface containing silver through a synergistic effect with Component (A).

As the organic acids and salts thereof, compounds having a carboxyl group or a compound having a sulfo group are preferable. Examples of compounds having a carboxyl group include stearic acid, lauric acid, oleic acid, myristic acid, alkenylsuccinic acid, lactic acid, tartaric acid, fumaric acid, glycolic acid, phthalic acid, maleic acid, formic acid, acetic acid, oxalic acid, citric acid, malic acid, malonic acid, glutaric acid, succinic acid, benzoic acid, quinolinic acid, quinaldic acid, amidosulfuric acid, propionic acid, trifluoroacetic acid; amino acid such as glycine, alanine, aspartic acid, glutamic acid, lysine, arginine, tryptophan, dodecylaminoethylaminoethylglycine, aromatic amino acid, heterocyclic amino acid; imino acid such as alkyliminodicarboxylic acid; and salts thereof. Examples of compounds having a sulfo group include alkylbenzenesulfonic acid such as dodecylbenzenesulfonic acid and p-toluenesulfonic acid; alkylnaphthalenesulfonic acid such as butylnaphthalenesulfonic acid; α-olefinsulfonic acid such as tetradecenesulfonic acid. These compounds may be used alone or in combination of two or more.

In the case where the composition for chemical mechanical polishing according to the embodiment includes an organic acid (salt), the content of the organic acid (salt) is preferably 0.001 mass % or more, more preferably 0.01 mass % or more, based on 100 mass % of the total mass of the composition for chemical mechanical polishing. The content of the organic acid (salt) is preferably 5 mass % or less, more preferably 1 mass % or less, based on 100 mass % of the total mass of the composition for chemical mechanical polishing.

### <Phosphate Esters>

The composition for chemical mechanical polishing according to the embodiment may include a phosphate ester. The phosphate ester may be able to enhance the effect of reducing the occurrence of dishing by being adsorbed onto the surface of the polished surface containing silver.

In general, a phosphate ester refers to a compound having a structure in which all or some of the three hydrogen atoms possessed by phosphoric acid (O═P(OH)₃) are substituted with an organic group. Among phosphate esters, polyoxyethylene alkyl ether phosphate ester can be preferably used due to the particularly high effect in reducing the occurrence of dishing. Polyoxyethylene alkyl ether phosphate ester is a nonionic anionic surfactant and can be represented by the following general formula (5).

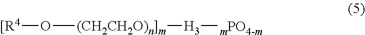

In the above formula (5), R⁴ represents a hydrocarbon group with 10 or more carbon atoms, n is 5 or more and less than 30, and m is 1 or 2. As the hydrocarbon group with 10 or more carbon atoms represented by R⁴, an alkyl group with 10 or more carbon atoms represented by R⁴ is preferable, and an alkyl group with 10 or more and 30 or less carbon atoms is more preferable. Specific examples of the alkyl group with 10 to 30 carbon atoms include a decyl group, an isodecyl group, a lauryl group, a tridecyl group, a cetyl group, an oleyl group, a stearyl group, etc. In the above formula (5), in the case where m=2, the two R⁴ may be the same group or may be a combination of multiple groups. The molecular weight of such polyoxyethylene alkyl ether phosphate ester is typically 400 or more.

Specific examples of the polyoxyethylene alkyl ether phosphate ester include phosphate monoester of polyoxyethylene decyl ether, phosphate diester of polyoxyethylene decyl ether, phosphate monoester of polyoxyethylene isodecyl ether, phosphate diester of polyoxyethylene isodecyl ether, phosphate monoester of polyoxyethylene lauryl ether, phosphate diester of polyoxyethylene lauryl ether, phosphate monoester of polyoxyethylene tridecyl ether, phosphate diester of polyoxyethylene tridecyl ether, phosphate monoester of polyoxyethylene allyl phenyl ether, phosphate diester of polyoxyethylene allyl phenyl ether, etc. These can be used alone or in combination of two or more types. Additionally, these polyoxyethylene alkyl ether phosphate esters include monoesters and diesters, etc., and in the composition for chemical mechanical polishing according to the embodiment, the monoesters and diesters may be used individually or as a mixture.

In the case where the composition for chemical mechanical polishing according to the embodiment includes a phosphate ester, the content of the phosphate ester is preferably 0.001 mass % or more, more preferably 0.002 mass % or more, based on 100 mass % of the total mass of the composition for chemical mechanical polishing. The content of the phosphate ester is preferably 0.1 mass % or less, more preferably 0.01 mass % or less, when the total mass of the composition for chemical mechanical polishing is taken as 100 mass %.

### <Water-Soluble Polymer>

The composition for chemical mechanical polishing according to the embodiment may include a water-soluble polymer. The water-soluble polymer may be adsorbed to the surface of the polished surface containing silver, reduce polishing friction, and be able to reduce the occurrence of dishing on the polished surface.

Specific examples of the water-soluble polymer include polycarboxylic acid, polystyrene sulfonic acid, polyacrylic acid, polymethacrylic acid, polyether, polyacrylamide, polyvinyl alcohol, polyvinylpyrrolidone, polyethyleneimine, polyallylamine, hydroxyethyl cellulose, etc. These can be used alone or in combination of two or more types.

The weight average molecular weight (Mw) of the water-soluble polymer is preferably 5,000 or more and 800,000 or less, more preferably 7,000 or more and 100,000 or less. Here, “weight average molecular weight” refers to the weight average molecular weight converted to polyethylene glycol equivalent as measured by gel permeation chromatography (GPC).

In the case where the composition for chemical mechanical polishing according to the embodiment includes a water-soluble polymer, the content of the water-soluble polymer is preferably 0.001 mass % or more, more preferably 0.002 mass % or more, when the total mass of the composition for chemical mechanical polishing is taken as 100 mass %. The content of the water-soluble polymer is preferably 0.1 mass % or less, more preferably 0.01 mass % or less, when the total mass of the composition for chemical mechanical polishing is taken as 100 mass %.

### <Surfactant>

The surfactant is not particularly limited, and an anionic surfactant, a cationic surfactant, a nonionic surfactant, etc., can be used. Examples of the anionic surfactant include sulfate such as alkyl ether sulfate, polyoxyethylene alkylphenyl ether sulfate; fluorine-containing surfactants such as perfluoroalkyl compounds, etc. Examples of the cationic surfactant include aliphatic amine salt, aliphatic ammonium salt, etc. Examples of the nonionic surfactant include nonionic surfactants having a triple bond such as acetylene glycol, acetylene glycol ethylene oxide adducts, acetylene alcohol; polyethylene glycol-type surfactants, etc. These surfactants can be used alone or in combination of two or more types.

### <Inorganic Acids and Salts Thereof>

The inorganic acid is preferably at least one selected from hydrochloric acid, nitric acid, sulfuric acid, and phosphoric acid. It should be noted that the inorganic acid may form a salt with a base separately added in the composition for chemical mechanical polishing.

### <Basic Compound>

As the basic compound, examples may include organic and inorganic bases. As the organic base, amine is preferable, and examples may include triethylamine, monoethanolamine, tetramethylammonium hydroxide, tetrabutylammonium hydroxide, benzylamine, methylamine, ethylenediamine, diglycol amine, isopropylamine, etc. As the inorganic base, examples may include ammonia, potassium hydroxide, sodium hydroxide, etc. Among the basic compounds, ammonia and potassium hydroxide are preferable. These basic compounds can be used alone or in combination of two or more types.

### 1.6 pH

The pH of the composition for chemical mechanical polishing according to the embodiment is preferably 1 or more and 6 or less, more preferably 1 or more and 5 or less, and particularly preferably 2 or more and 4 or less. When the pH is within the range, the absolute value of the zeta potential of Component (A) in the composition for chemical mechanical polishing increases, thereby improving the dispersibility. As a result, high-speed polishing can be performed while the occurrence of polishing scratches and dishing on the polished surface containing silver can be reduced.

It should be noted that the pH of the composition for chemical mechanical polishing according to the embodiment can be adjusted by appropriately increasing or decreasing the content of the organic acid and the salt thereof, the inorganic acid and the salt thereof, and the basic compound as needed.

In the invention, pH refers to the hydrogen ion index, and the value thereof can be measured by using a commercially available pH meter (for example, a tabletop pH meter manufactured by HORIBA, Ltd.) under the condition of 25° C. and 1 atmosphere pressure.

### 1.7 Application

The composition for chemical mechanical polishing according to the embodiment is suitable as a polishing material for chemical mechanical polishing of a semiconductor substrate having multiple types of materials forming a semiconductor device. The semiconductor substrate to be polished may include, in addition to silver as a conductive metal, an insulating film material such as silicon oxide, silicon nitride, amorphous silicon, polysilicon, etc., and a barrier metal material such as titanium, titanium nitride, tantalum nitride, etc.

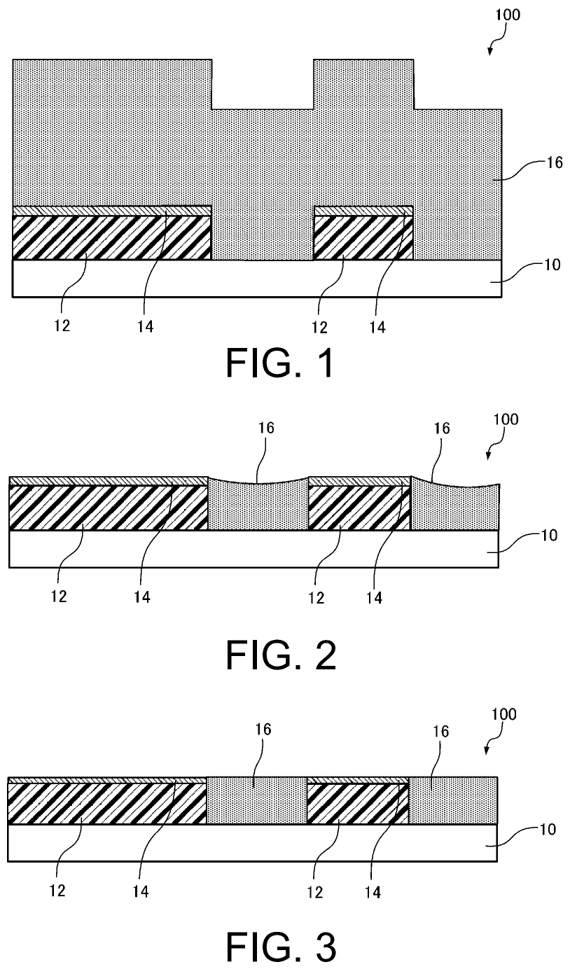

The polishing target of the composition for chemical mechanical polishing according to the embodiment is preferably a semiconductor substrate including a portion containing silver. As a specific example of such semiconductor substrate, examples may include a semiconductor substrate as shown in FIG. 1, which has a tantalum nitride film as a barrier metal and a silicon oxide film as an insulating film applied as an underlayer for a silver film as a conductive metal. According to the composition for chemical mechanical polishing of the embodiment, such a semiconductor substrate can be polished at high speed, and the occurrence of corrosion and polishing scratches on the polished surface after polishing can be effectively reduced. As a result, an excellent polished surface with high reflective properties is obtained.

### 1.8 Method for Preparing the Composition for Chemical Mechanical Polishing

The composition for chemical mechanical polishing according to the embodiment can be prepared by dissolving or dispersing the respective components in a liquid medium such as water. The method of dissolving or dispersing is not particularly limited, and any method can be applied as long as the components can be uniformly dissolved or dispersed. In addition, the order or the method of mixing the respective components is not particularly limited.

The composition for chemical mechanical polishing according to the embodiment can also be prepared as a concentrated stock solution and diluted with a liquid medium such as water at the time of use.

### 2. POLISHING METHOD

A polishing method according to an embodiment of the invention includes a step of polishing a semiconductor substrate by using the composition for chemical mechanical polishing. Such a semiconductor substrate preferably includes a portion containing silver. The composition for chemical mechanical polishing can be used to perform high-speed polishing on a polished surface containing silver, and can effectively reduce the occurrence of corrosion and polishing scratches on the polished surface after polishing. Therefore, an excellent polished surface with high reflective properties is obtained. The polished surface may also include a barrier metal film containing tantalum or titanium, and/or an insulating film such as silicon oxide or hafnium oxide. A specific example of the polishing method according to the embodiment will be described in detail below with reference to the drawings.

### 2.1 Processed Body

FIG. 1 is a cross-sectional view schematically showing a processed body suitable for use in a polishing method according to the embodiment. A processed body 100 is formed through Steps (1) to (4) below.
(1) Firstly, as shown in FIG. 1, abase 10 is prepared. The base 10 may be formed from, for example, a silicon substrate and a silicon oxide film formed thereon. Furthermore, a functional device such as (not shown) a transistor may be formed on the base 10. Next, a silicon oxide film 12, which is an insulating film, is formed on the base 10 using a thermal oxidation method.
(2) Next, a tantalum nitride film 14 is formed on the silicon oxide film 12. The tantalum nitride film 14 can be formed, for example, by performing a chemical vapor deposition (CVD) process or a physical vapor deposition (PVD) process.
(3) Then, a photosensitive resist film is formed on the tantalum nitride film 14 by using a spin coater, selectively exposed by using a photomask, and developed. Then, plasma is irradiated to etch a portion without the resist. After that, the resist for protection is removed.
(4) Then, a silver film 16 with a thickness of 16,000 Å is deposited by performing a physical vapor deposition (PVD) process. With Steps (1) to (4) as the above, the processed body 100 can be prepared.

### 2.2 Polishing Method

### 2.2.1 First Polishing Step

FIG. 2 is a cross-sectional view schematically showing the processed body 100 at the end of a first polishing step. As shown in FIG. 2, the first polishing step is a step of rough-polishing the silver film 16 by using a composition for chemical mechanical polishing capable of high-speed polishing of the silver film 16. In the first polishing step, due to the use of the composition for chemical mechanical polishing capable of performing high-speed polishing on a silver film, a surface defect referred to as dishing, as shown in FIG. 2, may occur on the surface of the silver film 16.

### 2.2.2 Second Polishing Step

FIG. 3 is a cross-sectional view schematically showing the processed body 100 at the end of a second polishing step. As shown in FIG. 3, the second polishing step is a step of polishing to planarize the tantalum nitride film 14 and the silver film 16 by using the composition for chemical mechanical polishing (of the invention). The composition for chemical mechanical polishing (of the invention) can control the polishing rates of the tantalum nitride film 14 and the silver film 16 in a well-balanced manner, thus being able to reduce the occurrence of dishing in the silver film 16 and perform planarization by polishing the exposed tantalum nitride film 14 and silver film 16 at high speed and in a well-balanced manner. Additionally, the composition for chemical mechanical polishing (of the invention) has favorable dispersibility of Component (A), thereby reducing the occurrence of polishing scratches on the polished surface.

### 2.3 Chemical Mechanical Polishing Device

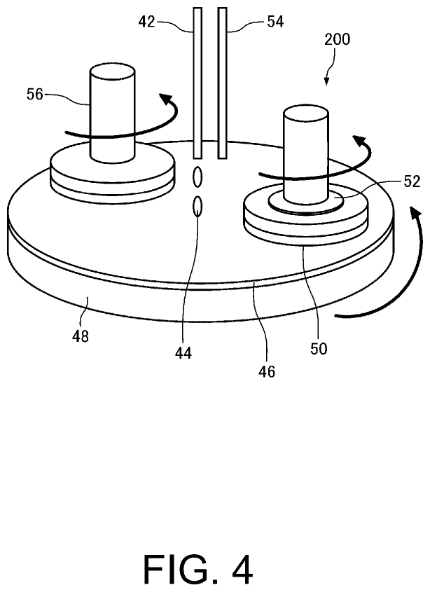

A polishing device 200 as shown in FIG. 4, for example, can be used in the first polishing step and second polishing step. FIG. 4 is a schematic perspective view showing the polishing device 200. The first polishing step and the second polishing step are performed by supplying a slurry 44 (composition for chemical mechanical polishing) from a slurry feed nozzle 42, and bringing a carrier head 52 holding a semiconductor substrate 50 into contact while rotating a turntable 48 to which a polishing pad 46 is attached. In addition, FIG. 4 also shows a water supply nozzle 54 and a dresser 56.

The polishing load of the carrier head 52 can be selected within a range of 0.7 psi to 70 psi, preferably 1.5 psi to 35 psi. In addition, the rotation speeds of the turntable 48 and the carrier head 52 can be appropriately selected within the range of 10 rpm to 400 rpm, preferably 30 rpm to 150 rpm. The flow rate of the slurry 44 (composition for chemical mechanical polishing) supplied from the slurry feed nozzle 42 can be selected within the range of 10 mL/min to 1,000 mL/min, preferably within the range of 50 mL/min to 400 mL/min.

Examples of commercially available polishing devices include: models “EPO-112” and “EPO-222” manufactured by Ebara Corporation; models “LGP-510” and “LGP-552” manufactured by Lapmaster SFT; models “Mirra” and “Reflexion” manufactured by Applied Materials; model “POLI-400L” manufactured by G&P TECHNOLOGY; and model “Reflexion LK” manufactured by AMAT.

### 3. EXAMPLES

The invention will be described below by examples, but the invention is not limited in any way by these examples. In these examples, “parts” and “%” are on a mass basis unless otherwise specified.

### 3.1 Preparation of Abrasive Grains

### <Preparation of Abrasive Grains A>

5 kg of high-purity colloidal silica (product number: PL-1; silica concentration 12 mass %) manufactured by Fuso Chemical Co., Ltd. and 6 g of 3-mercaptopropyltrimethoxysilane were mixed and heated under reflux for 2 hours to obtain a thiolated silica sol. Hydrogen peroxide was added to the silica sol and heated under reflux for 8 hours to oxidize the surfaces of the silica particles and immobilize the sulfo groups. In this manner, a dispersion body containing 12 mass % of abrasive grains A, which had an average primary particle diameter of 20 nm and an average secondary particle diameter of 38 nm, with the silica surface modified with sulfo groups, was obtained.

### <Preparation of Abrasive Grains B>

5 kg of high-purity colloidal silica (product number: PL-3; silica concentration 20 mass %) manufactured by Fuso Chemical Co., Ltd. and 6 g of 3-mercaptopropyltrimethoxysilane were mixed and heated under reflux for 2 hours to obtain a thiolated silica sol. Hydrogen peroxide was added to the silica sol and heated under reflux for 8 hours to oxidize the surfaces of the silica particles and immobilize the sulfo groups. In this manner, a dispersion body containing 20 mass % of abrasive grains B, which had an average primary particle diameter of 45 nm and an average secondary particle diameter of 68 nm, with the silica surface modified with sulfo groups, was obtained.

### <Preparation of Abrasive Grains C>

900 g of high-purity colloidal silica (product number: PL-3; silica concentration 20 mass %) manufactured by Fuso Chemical Co., Ltd. was dispersed in a mixed solvent of 100 g of pure water and 2850 g of methanol, and then 50 g of 29% ammonia water was added. 40.0 g of 3-(triethoxysilyl)propylsuccinic anhydride was added to the dispersed liquid and refluxed at the boiling point for 6 hours. Subsequently, pure water was further added to maintain the volume of the dispersed liquid while replacing methanol and ammonia with water. The addition of pure water was terminated when the pH of the dispersed liquid became 8.5 or lower and the overhead temperature reached 100° C. The dispersed liquid was left to stand until the temperature became 30° C. or lower. In this manner, a dispersion body containing 14 mass % of abrasive grains C, which had an average primary particle diameter of 47 nm and an average secondary particle diameter of 69 nm, with the silica surface modified with carboxyl groups, was obtained.

### <Preparation of Abrasive Grains D>

1000 g of high-purity colloidal silica (product number: PL-3; silica concentration 20 mass %) manufactured by Fuso Chemical Co., Ltd. was dispersed in a mixed solvent of 100 g of pure water and 2850 g of methanol, and then 5.0 g of 3-aminopropyltrimethoxysilane was added, and the dispersed liquid was refluxed at the boiling point for 4 hours. Subsequently, pure water was further added to maintain the volume of the dispersed liquid while replacing methanol with water. The addition of pure water was terminated when the overhead temperature reached 100° C., and the dispersed liquid was left to stand until the temperature became 30° C. or lower. In this manner, a dispersion body containing 15 mass % of abrasive grains D, which had an average primary particle diameter of 46 nm and an average secondary particle diameter of 69 nm, with the silica surface modified with amino groups, was obtained.

### <Measurement of Average Primary Particle Diameter and Average Secondary Particle Diameter>

The average primary particle diameters of abrasive grains A to D were calculated according to the method described in Japanese Laid-Open No. 2004-315300. Specifically, after preliminary drying of the respective dispersion bodies of the abrasive grains on a hot plate, a heat treatment was performed for one hour at 800° C., and the specific surface area was measured by the nitrogen adsorption method (BET method, using “BELSORP MR6” manufactured by Microtrac). The primary particle diameter (nm) was calculated using the formula: 2727/specific surface area (m²/g), assuming the true specific gravity of silica to be 2.2. The average secondary particle diameters of abrasive grains A to D were determined by calculation using the dynamic light scattering method with “Zetasizer Ultra” manufactured by Malvern.

### 3.2 Preparation of the Composition for Chemical Mechanical Polishing

The abrasive grains described in Tables 1 to 2 were added to a 10L polyethylene bottle to achieve the specified concentration. The respective components were added to obtain the compositions shown in Tables 1 to 2, and the pH was adjusted by using an ammonia (manufactured by FUJIFILM Wako Pure Chemical Corporation, trade name “Ammonia Water”) aqueous solution to achieve the pH values shown in Tables 1 to 2. Pure water was added as (B) liquid medium to adjust the total amount of all components to 100 mass %, thereby preparing the compositions for chemical mechanical polishing for the respective examples and comparative examples. The zeta potentials of the abrasive grains in the respective compositions for chemical mechanical polishing so obtained were measured using a zeta potential measuring device (manufactured by Malvern, model “Zetasizer Ultra”), and the results are also shown in Tables 1 to 2.

### 3.3 Evaluation Method

### 3.3.1 Polishing Rate Evaluation

By using the compositions for chemical mechanical polishing as obtained above, chemical mechanical polishing tests were performed for 30 seconds under the following polishing conditions through using a 12-inch diameter wafer with a 6000 Å silver film, a 12-inch diameter wafer with a 2000 Å tantalum nitride film, and a 12-inch diameter wafer with a 10000 Å silicon oxide film as processed bodies, respectively.

### <Polishing Conditions>

Polishing device: Manufactured by G&P TECHNOLOGY, model “POLI-762L”
Polishing pad: Manufactured by Nitta-DuPont, “IC1000XYP”
Composition for chemical mechanical polishing supply rate: 300 mL/min
Turntable rotation speed: 87 rpm
Carrier head rotation speed: 93 rpm
Carrier head pressure: 2 psi

Polishing rate (Å/min)=(Film thickness before polishing (Å)−Film thickness after polishing (Å))/Polishing time (min)

The thicknesses of the silver film and the tantalum nitride film were calculated by using the following equation through the sheet resistance value and the volume resistivity of silver or tantalum nitride. The resistance was measured by the direct current four-probe method using a resistivity measurement device (manufactured by International Electric Semiconductor Service, model “VR300DEC”).

Film thickness (Å)=[Volume resistivity of silver or tantalum nitride film (Ω·m)+Sheet resistance value (Ω)]×10\hat{ }10

The thickness of the silicon oxide film was calculated by measuring the refractive index using a non-contact optical film thickness measurement device (manufactured by SCREEN Holdings Co., Ltd., model “VM-1310”).

The evaluation criteria for the polishing rate are as follows. The polishing rates of the silver film, the tantalum nitride film, and the silicon oxide film, as well as the evaluation results of the polishing rates are also shown in Tables 1 to 2.

### (Evaluation Criteria)

“A” . . . In the case where the polishing rate of the silver film is 500 Å/min or more, it is determined to be favorable because the polishing time of the wiring can be significantly reduced in actual semiconductor polishing.
“B” . . . In the case where the polishing rate of the silver film is less than 500 Å/min, it is determined to be unfavorable because the polishing rate is low and it is difficult to be put into practical use.

### 3.3.2 Measurement of Reflectance of Silver Film after Polishing

By using the compositions for chemical mechanical polishing obtained above, a chemical mechanical polishing test was performed for 30 seconds under the following polishing conditions through using a 12-inch diameter wafer with a 6000 Å silver film as the processed body. In the case where corrosion or polishing scratches occur on silver, the reflectance of silver decreases. Therefore, the corrosion and polishing scratches on the polished surface of the silver film can be evaluated by evaluating the reflectance.

### <Polishing Conditions>

Polishing device: Manufactured by G&P TECHNOLOGY, model “POLI-762L”
Polishing pad: Manufactured by Nitta-DuPont, “IC1000XYP”
Composition for chemical mechanical polishing supply rate: 300 mL/min
Turntable rotation speed: 87 rpm
Carrier head rotation speed: 93 rpm
Carrier head pressure: 2 psi
   The reflectance at 459 nm was measured by using a non-contact optical film thickness measurement device (manufactured by Filmetrics, Model “F40-UV”).

The evaluation criteria for the reflectance are as follows. The evaluation results of the reflectance are also shown in Tables 1 to 2.

### (Evaluation Criteria)

“A” . . . In the case where the reflectance is 92% or higher, it is determined that the corrosion and polishing scratches on the silver film surface are minimal and satisfactory.
“B” . . . In the case where the reflectance is less than 92%, it is determined that the corrosion or polishing scratches on the silver film surface are excessive and unsatisfactory.

### 3.4 Evaluation Results

Tables 1 to 2 show the components of the compositions for chemical mechanical polishing for the respective examples and comparative examples, as well as the respective evaluation results thereof.

TABLE 1

| | | | Example | Example | Example | Example | Example | Example | Example |
|---|---|---|---|---|---|---|---|---|---|
| | | | 1 | 2 | 3 | 4 | 5 | 6 | 7 |
| Composition | (A) | Type | Abrasive | Abrasive | Abrasive | Abrasive | Abrasive | Abrasive | Abrasive |
| for | Abrasive | | Grain A | Grain A | Grain A | Grain A | Grain A | Grain A | Grain B |
| CMP | Grain | Zeta | −22.5 | −23.0 | −24.1 | −18.2 | −20.5 | −25.6 | −20.1 |
| | | potential(mV) | | | | | | | |
| | | Absolute | 22.5 | 23.0 | 24.1 | 18.2 | 20.5 | 25.6 | 20.1 |
| | | value of | | | | | | | |
| | | Zeta | | | | | | | |
| | | potential | | | | | | | |
| | | Content | 0.5 | 1.0 | 2.0 | 0.5 | 0.5 | 2.0 | 1.2 |
| | | (mass %) | | | | | | | |
| | (C) | Type | Hydrogen | Hydrogen | Hydrogen | Hydrogen | Hydrogen | Hydrogen | Hydrogen |
| | Oxidizing | | peroxide | peroxide | peroxide | peroxide | peroxide | peroxide | peroxide |
| | agent | Content Mc | 0.75 | 0.75 | 0.50 | 0.75 | 0.75 | 0.30 | 0.50 |
| | | (mass %) | | | | | | | |
| | (D) | Type | Benzo- | Benzo- | Benzo- | Benzo- | Benzo- | 2,2′-[[(Methyl-1H- | Carboxy- |
| | Nitrogen- | | triazole | triazole | triazole | triazole | triazole | benzotriazole-1-yl) | benzotriazole |
| | containing | | | | | | | methyl]imino] | |
| | heterocyclic | | | | | | | bisethanol | |
| | compound | Content Md | 0.005 | 0.010 | 0.025 | 0.040 | 0.065 | 0.010 | 0.015 |
| | | (mass %) | | | | | | | |
| | Mc/Md | | 150 | 75 | 20 | 19 | 12 | 30 | 33 |
| | Acid | Type | Nitric | Nitric | Nitric | Nitric | Nitric | Nitric acid | Nitric |
| | | | acid | acid | acid | acid | acid | | acid |
| | | Content (mass %) | 0.077 | 0.077 | 0.050 | 0.077 | 0.077 | 0.080 | 0.040 |
| | Other | Type | | | | Tetraethylam | Polyacrylic | Polyoxyethylene | Polyvinyl |
| | additive | | | | | monium | acid | allylphenyl phosphate | pyrrolidone |
| | | | | | | hydroxide | | amine salt | |
| | | Content (mass %) | | | | 0.03 | 0.003 | 0.003 | 0.075 |
| | pH | | 2.1 | 2.3 | 2.7 | 2.1 | 2.1 | 2.8 | 3.0 |
| Evaluation | Polishing | Polishing rate of | 2700 | 2349 | 1050 | 730 | 604 | 1407 | 821 |
| Category | properties | Ag film (Å/min) | | | | | | | |
| | of Ag film | Polishing rate of | 1310 | 1400 | 1666 | 1299 | 1000 | 1474 | 1451 |
| | | tantalum nitride | | | | | | | |
| | | film | | | | | | | |
| | | (Å/min) | | | | | | | |
| | | Polishing rate of | 64 | 80 | 101 | 60 | 55 | 89 | 132 |
| | | silicon oxide film | | | | | | | |
| | | (Å/min) | | | | | | | |
| | | Evaluation | A | A | A | A | A | A | A |
| | | Reflectance of | 92 | 94 | 94 | 95 | 95 | 93 | 93 |
| | | Ag film (%) | | | | | | | |
| | | Evaluation | A | A | A | A | A | A | A |

| | | | Example | Example | Example | Example | Example |
|---|---|---|---|---|---|---|---|
| | | | 8 | 9 | 10 | 11 | 12 |
| Composition | (A) | Type | Abrasive | Abrasive | Abrasive | Abrasive | Abrasive |
| for | Abrasive | | Grain B | Grain C | Grain D | Grain A | Grain A |
| CMP | Grain | Zeta | −28.0 | −11.5 | 32.0 | −15.0 | −21.5 |
| | | potential(mV) | | | | | |
| | | Absolute | 28.0 | 11.5 | 32.0 | 15.0 | 21.5 |
| | | value of | | | | | |
| | | Zeta | | | | | |
| | | potential | | | | | |
| | | Content | 0.5 | 0.5 | 0.4 | 1.0 | 0.5 |
| | | (mass %) | | | | | |
| | (C) | Type | Hydrogen | Hydrogen | Hydrogen | Hydrogen | Hydrogen |
| | Oxidizing | | peroxide | peroxide | peroxide | peroxide | peroxide |
| | agent | Content Mc | 0.60 | 0.75 | 0.55 | 0.50 | 0.50 |
| | | (mass %) | | | | | |
| | (D) | Type | 1,2,4- | Benzo- | Benzo- | Benzo- | 1-(2,3- |
| | Nitrogen- | | Triazole | triazole | triazole | triazole | Dicarboxypropyl) |
| | containing | | | | | | benzotriazole |
| | heterocyclic | | | | | | |
| | compound | Content Md | 0.020 | 0.015 | 0.003 | 0.025 | 0.005 |
| | | (mass %) | | | | | |
| | Mc/Md | | 30 | 50 | 183 | 20 | 100 |
| | Acid | Type | Nitric | Nitric | Nitric | Nitric | Nitric acid |
| | | | acid | acid | acid | acid | |
| | | Content (mass %) | 0.077 | 0.050 | 0.030 | 0.150 | 0.077 |
| | Other | Type | Polyethylene | | Citric | Tetraethylammonium | |
| | additive | | glycol | | acid | hydroxide | |
| | | Content (mass %) | 0.01 | | 0.03 | 0.03 | |
| | pH | | 2.1 | 3.3 | 3.1 | 3.0 | 2.3 |
| Evaluation | Polishing | Polishing rate of | 2202 | 1654 | 1654 | 2444 | 2433 |
| Category | properties | Ag film (Å/min) | | | | | |
| | of Ag film | Polishing rate of | 1587 | 889 | 291 | 1393 | 1274 |
| | | tantalum nitride | | | | | |
| | | film | | | | | |
| | | (Å/min) | | | | | |
| | | Polishing rate of | 89 | 100 | 215 | 75 | 55 |
| | | silicon oxide film | | | | | |
| | | (Å/min) | | | | | |
| | | Evaluation | A | A | A | A | A |
| | | Reflectance of | 92 | 92 | 92 | 92 | 93 |
| | | Ag film (%) | | | | | |
| | | Evaluation | A | A | A | A | A |

TABLE 2

| | | | Comparative | Comparative | Comparative |
|---|---|---|---|---|---|
| | | | Example 1 | Example 2 | Example 3 |
| Composition | (A) | Type | Abrasive | Abrasive | Abrasive |
| | | | Grain A | Grain A | Grain B |
| for | Abrasive Grain | Zeta potential (mV) | −22.2 | −26.8 | −26.3 |
| CMP | | Absolute value of | 22.2 | 26.8 | 26.3 |
| | | Zeta potential | | | |
| | | Content (mass %) | 0.5 | 0.5 | 0.5 |
| | (C) | Type | Hydrogen | Hydrogen | |
| | Oxidizing | | peroxide | peroxide | |
| | agent | Content Mc | 0.20 | 0.75 | |
| | | (mass %) | | | |
| | (D) Nitrogen- | Type | Benzotriazole | | Benzotriazole |
| | containing | Content Md | 0.025 | | 0.010 |
| | heterocyclic | (mass %) | | | |
| | compound | | | | |
| | Mc/Md | | 8 | — | 0 |
| | Acid | Type | Nitric acid | Nitric acid | Nitric acid |
| | | Content (mass %) | 0.077 | 0.077 | 0.077 |
| | Other additive(s) | Type | Tetraethylammonium | | Tetraethylammonium |
| | | | hydroxide | | hydroxide |
| | | Content (mass %) | 0.005 | | 0.01 |
| | pH | | 2.1 | 2.1 | 2.5 |
| Evaluation | Polishing | Polishing rate of | 452 | 9749 | 51 |
| Category | properties | Ag film (Å/min) | | | |
| | of Ag film | Polishing rate of | 1464 | 1395 | 105 |
| | | tantalum nitride | | | |
| | | film (Å/min) | | | |
| | | Polishing rate of | 64 | 63 | 98 |
| | | silicon oxide | | | |
| | | film (Å/min) | | | |
| | | Evaluation | B | A | B |
| | | Reflectance of | 94 | 86 | 88 |
| | | Ag film (%) | | | |
| | | Evaluation | A | B | B |

| | | | Comparative | Comparative | Comparative |
|---|---|---|---|---|---|
| | | | Example 4 | Example 5 | Example 6 |
| Composition | (A) | Type | Abrasive | PL-1 | PL-3 |
| | | | Grain A | | |
| for | Abrasive Grain | Zeta potential (mV) | −23.5 | −1.0 | −2.1 |
| CMP | | Absolute value of | 23.5 | 1.0 | 2.1 |
| | | Zeta potential | | | |
| | | Content (mass %) | 0.5 | 0.5 | 0.5 |
| | (C) | Type | Hydrogen | Hydrogen | Hydrogen |
| | Oxidizing | | peroxide | peroxide | peroxide |
| | agent | Content Mc | 2.10 | 0.50 | 0.60 |
| | | (mass %) | | | |
| | (D) Nitrogen- | Type | Benzotriazole | Benzotriazole | Benzotriazole |
| | containing | Content Md | 0.010 | 0.020 | 0.010 |
| | heterocyclic | (mass %) | | | |
| | compound | | | | |
| | Mc/Md | | 210 | 25 | 60 |
| | Acid | Type | Nitric acid | Nitric acid | Nitric acid |
| | | Content (mass %) | 0.077 | 0.050 | 0.050 |
| | Other additive(s) | Type | | | |
| | | Content (mass %) | | | |
| | pH | | 2.1 | 2.5 | 2.6 |
| Evaluation | Polishing | Polishing rate of | 9400 | 1075 | 1075 |
| Category | properties | Ag film (Å/min) | | | |
| | of Ag film | Polishing rate of | 741 | 247 | 329 |
| | | tantalum nitride | | | |
| | | film (Å/min) | | | |
| | | Polishing rate of | 70 | 77 | 166 |
| | | silicon oxide | | | |
| | | film (Å/min) | | | |
| | | Evaluation | A | A | A |
| | | Reflectance of | 85 | 91 | 87 |
| | | Ag film (%) | | | |
| | | Evaluation | B | B | B |

The respective components in Tables 1 to 2 were prepared using the following products or reagents, respectively.

### <Abrasive Grains>

Abrasive grain A: Colloidal silica with surface modified with sulfo groups prepared as described above, with the average secondary particle diameter of 38 nm
Abrasive grain B: Colloidal silica with surface modified with sulfo groups prepared as described above, with the average secondary particle diameter of 68 nm
Abrasive grain C: Colloidal silica with surface modified with carboxyl groups prepared as described above, with the average secondary particle diameter of 69 nm
Abrasive grain D: Colloidal silica with surface modified with amino groups prepared as described above, with the average secondary particle diameter of 69 nm
PL-1: Ultra-high purity unmodified colloidal silica manufactured by Fuso Chemical Co., Ltd., with the average secondary particle diameter of 40 nm
PL-3: Ultra-high purity unmodified colloidal silica manufactured by Fuso Chemical Co., Ltd., with the average secondary particle diameter of 70 nm

### <Oxidizing Agent>

Hydrogen peroxide: Manufactured by FUJIFILM Wako Pure Chemical Corporation, trade name “Hydrogen Peroxide”

### <Nitrogen-Containing Heterocyclic Compound>

Benzotriazole: Manufactured by Johoku Chemical Co., Ltd., trade name “BT-120SG”
2,2′-[[(Methyl-1H-benzotriazole-1-yl)methyl]imino]bisethanol: Manufactured by Johoku Chemical Co., Ltd., trade name “TT-LYK”
Carboxybenzotriazole: Manufactured by Johoku Chemical Co., Ltd., trade name “CBT-SG”
1,2,4-Triazole: Manufactured by Tokyo Chemical Industry Co., Ltd., trade name “1,2,4-Triazole”
1-(2,3-Dicarboxypropyl)benzotriazole: Manufactured by Johoku Chemical Co., Ltd., trade name “BT-250”

### <Acid>

Nitric acid: Manufactured by FUJIFILM Wako Pure Chemical Corporation, trade name “Nitric Acid (1.38)”

### <Other Additives>

### (Basic Compound)

Tetraethylammonium hydroxide: Manufactured by Tokyo Chemical Industry Co., Ltd., trade name “Tetraethylammonium Hydroxide (10% in Water)”

### (Water-Soluble Polymer)

Polyacrylic acid: Manufactured by Toagosei Co., Ltd., trade name “JULIMER AC-10L”
Polyvinylpyrrolidone: Manufactured by Tokyo Chemical Industry Co., Ltd., trade name “Polyvinylpyrrolidone K 15 Average Molecular Wt. 10000”
Polyethylene glycol: Manufactured by Toho Chemical Industry Co., Ltd., trade name “PEG-400”

### (Phosphate Esters)

Polyoxyethylene allyl phenyl phosphate amine salt: Manufactured by Takemoto Oil & Fat Co., Ltd., trade name “NEWCALGEN FS-3AQ” (20% aqueous solution)

### (Organic Acid)

Citric acid: Manufactured by Fuso Chemical Co., Ltd., trade name “Refined Citric Acid (Crystal)

The compositions for chemical mechanical polishing of Examples 1 to 12 were found to be capable of polishing the polished surface containing silver at high speed, and effectively reducing the occurrence of corrosion and polishing scratches on the polished surface after polishing, resulting in a polished surface with excellent high reflective properties.

The compositions for chemical mechanical polishing of Comparative Examples 1 and 3 are examples where the values of Mc/Md were less than 10 or examples which did not include Component (C). In such case, it was found that the polishing rate of the silver film significantly decreased.

The compositions for chemical mechanical polishing of Comparative Examples 2 and 4 are examples where the values of Mc/Md were 200 or more or examples which did not include Component (D). In such case, it was found that the occurrence of corrosion and polishing scratches on the polished surface after polishing cannot be suppressed, resulting in a lower reflectance of the silver film.

The compositions for chemical mechanical polishing of Comparative Examples 5 and 6 are examples where the absolute value of the zeta potential of Component (A) was less than 10 mV. In such case, it was found that Component (A) was prone to aggregation, and the aggregated abrasive grains caused polishing scratches on the surface of the silver film, resulting in a lower reflectance of the silver film.

The invention is not limited to the embodiments, and various modifications are possible. For example, the invention includes configurations substantially identical to those described in the embodiments (e.g., configurations with identical functions, methods, and results, or configurations with identical purposes and effects). In addition, the invention includes configurations in which non-essential parts of the configurations described in the embodiments are substituted. Furthermore, the invention includes configurations that produce the same operational effects as the configurations described in the embodiments or configurations that can achieve the same objectives. Moreover, the invention includes configurations that add known technologies to the configurations described in the embodiments.

### REFERENCE SIGNS LIST

10 . . . base, 12 . . . silicon oxide film, 14 . . . tantalum nitride film, 16 . . . silver film, 42 . . . slurry feed nozzle, 44 . . . slurry (composition for chemical mechanical polishing), 46 . . . pad for polishing, 48 . . . turntable, 50 . . . semiconductor substrate, 52 . . . carrier head, 54 . . . water supply nozzle, 56 . . . dresser, 100 . . . processed body, 200 . . . grinding device

1. A composition for chemical mechanical polishing, comprising:
(A) abrasive grains;
(B) a liquid medium;
(C) an oxidizing agent; and
(D) a nitrogen-containing heterocyclic compound,
wherein an absolute value of a zeta potential of (A) in the composition for chemical mechanical polishing is 10 mV or more, and
in a case where a content of (C) is set as Mc in mass %, and a content of (D) is set as Md in mass %, Mc/Md=100 to 200.

2. The composition for chemical mechanical polishing as claimed in claim 1, wherein (A) has a functional group represented by General Formula (1) as follows: 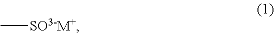
wherein M⁺ represents a monovalent cation.

3. The composition for chemical mechanical polishing as claimed in claim 2, wherein the zeta potential of (A) in the composition for chemical mechanical polishing is −10 mV or less.

4. The composition for chemical mechanical polishing as claimed in claim 1, wherein (A) has a functional group represented by General Formula (2) as follows: 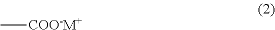
wherein M⁺ represents a monovalent cation.

5. The composition for chemical mechanical polishing as claimed in claim 4, wherein the zeta potential of (A) in the composition for chemical mechanical polishing is −10 mV or less.

6. The composition for chemical mechanical polishing as claimed in claim 1, wherein (A) has a functional group represented by General Formula (3) or General Formula (4) as follows: 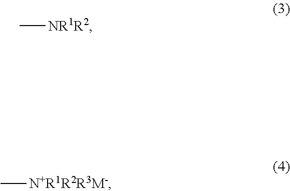
wherein in General Formula (3) and General Formula (4), R¹, R², and R³ each independently represent a hydrogen atom, or a substituted or unsubstituted hydrocarbon group, and M− represents an anion.

7. The composition for chemical mechanical polishing as claimed in claim 6, wherein the zeta potential of (A) in the composition for chemical mechanical polishing is +10 mV or more.

8. The composition for chemical mechanical polishing as claimed in claim 1, having a pH of 1 or more and 6 or less.

9. The composition for chemical mechanical polishing as claimed in claim 1, wherein, with respect to a total mass of the composition for chemical mechanical polishing, a content of (A) is 0.005 mass % or more and 15 mass % or less.

10. The composition for chemical mechanical polishing as claimed in claim 1, wherein (D) has an azole structure.

11. A polishing method, comprising a step of polishing a semiconductor substrate by using the composition for chemical mechanical polishing as claimed in claim 1.

12. The polishing method as claimed in claim 11, wherein the semiconductor substrate comprises a portion containing silver.
